(19) United States
(12) Patent Application Publication
(10) Pub. No.: US 2011/0120614 A1
(43) Pub. Date: May 26, 2011

(54) THERMOSETTING ADHESIVE FILM, ADHESIVE FILM WITH DICING FILM, AND METHOD OF MANUFACTURING SEMICONDUCTOR DEVICE USING THE THERMOSETTING ADHESIVE FILM OR THE ADHESIVE FILM WITH DICING FILM

(76) Inventors: Yuki Sugo, Osaka (JP); Kouichi Inoue, Osaka (JP); Kenji Oonishi, Osaka (JP)

(21) Appl. No.: 12/948,992

(22) Filed: Nov. 18, 2010

(30) Foreign Application Priority Data
Nov. 26, 2009 (JP) 2009-269087
Oct. 1, 2010 (JP) 2010-224088

(51) Int. Cl. H01L 21/50; B32B 5/00; B32B 3/00; C09J 7/00; C09J 7/02

(52) U.S. Cl. 156/60; 428/220; 428/141; 428/336

(57) ABSTRACT

The present invention provides a thermosetting adhesive film that is capable of improving the package reliability by preventing damage of a semiconductor chip due to pressure during die bonding of the film having a configuration where a filler is not substantially added, preventing a decrease of tensile storage modulus and preventing generation of warping due to heat shrinkage during thermosetting. It is a thermosetting adhesive film used at the time of manufacturing a semiconductor device, the film having a tensile storage modulus at 260° C. after thermosetting of 2×10⁵ to 5×10⁷ Pa, a content of a filler of 0.1% by weight or less based on the entire thermosetting adhesive film, and a thickness of 1 to 10 μm.

### BACKGROUND OF THE INVENTION

1. Field of the Invention

The present invention relates to a thermosetting adhesive film that is used when adhering and fixing a chip shaped work piece such as a semiconductor chip onto an adherend such as a substrate and a lead frame. Further, the present invention relates to an adhesive film with a dicing film in which the thermosetting adhesive film and the dicing film are laminated. Further, the present invention relates to a method of manufacturing a semiconductor device using the thermosetting adhesive film or the adhesive film with a dicing film.

2. Description of the Related Art

Conventionally, a silver paste has been used to fix a semiconductor chip to a lead frame or an electrode member in a process of manufacturing a semiconductor device. Such fixing process is performed by applying a paste-like adhesive onto a die pad of a lead frame, etc., mounting a semiconductor chip thereon, and then curing the paste-like adhesive layer.

However, a large variation occurs in the amount applied, the applied form, etc. of the paste-like adhesive due to its viscosity behavior, deterioration, etc. As a result, the thickness of the paste-like adhesive to be formed becomes nonunifrom, and therefore, reliability of the fixing strength of a semiconductor chip is poor. That is, when the amount of the paste-like adhesive applied is insufficient, the fixing strength between a semiconductor chip and an electrode member becomes small and the semiconductor chip is peeled in a subsequent wire bonding step. On the other hand, when the amount of the paste-like adhesive applied is too excessive, the paste-like adhesive flows out and spreads onto the semiconductor chip, characteristic failure occurs, and the yield and the reliability decrease. Such problems in the fixing process have become especially prominent as the size of the semiconductor chip becomes larger. For this reason, it is necessary to control the amount of the paste-like adhesive applied frequently, and workability and productivity are affected.

A method of applying the paste-like adhesive separately onto a lead frame or a formed chip may be used in the application step of the paste-like adhesive. However, it is difficult to form a uniform paste-like adhesive layer, and a special apparatus and a long time are necessary to apply the paste-like adhesive in this method. For this reason, a dicing die-bonding film has been proposed which adheres and holds a semiconductor wafer in a dicing step and which provides an adhesive layer for fixing a chip that is necessary in a mounting step (see, for example, Japanese Patent Application Laid-Open No. 60-57642).

This dicing die-bonding film is formed by providing a peelable adhesive layer on a support base. After a semiconductor chip is diced while being held by the adhesive layer, a formed chip is peeled together with the adhesive layer by stretching the support base, the chips are individually collected and fixed onto an adherend such as a lead frame through the adhesive layer.

On the other hand, a semiconductor chip in a semiconductor device typified by memory has been made thinner in recent years due to a limitation of the thickness of the package itself, and the chip has become very fragile. In a case where such a semiconductor chip is die-bonded to an adherend using a die-bonding film, there has been a problem that there is a possibility that a semiconductor chip is damaged when a filler exists in the die-bonding film, and this is caused by the generation of excessive stress between the semiconductor chip and the filler in the die-bonding film due to the pressure during die-bonding.

A method of solving this problem is to add no filler to the die-bonding film. However, if the filler is not added, a decrease of the tensile storage modulus of the die-bonding film is brought about and there has been a possibility that a new problem is generated such that the reliability of the package is decreased. Further, if the filler is not added, there has been a possibility that the semiconductor chip warps and is damaged due to heat shrinkage during thermosetting of the die-bonding film.

Further, not limited to the die-bonding film, there is a possibility that, in the thermosetting adhesive film having a configuration where no filler is added, a decrease of tensile storage modulus is brought about and the heat shrinkage of the film occurs during thermosetting.

### SUMMARY OF THE INVENTION

The present invention is performed in view of the above-described problems, and an object thereof is to provide a thermosetting adhesive film that is capable of preventing a decrease of tensile storage modulus and heat shrinkage during thermosetting even if a configuration where a filler is not practically added, and an adhesive film with a dicing film in which the thermosetting adhesive film and the dicing film are laminated. Especially, when the films are used as a die-bonding film, an object thereof is to provide a thermosetting adhesive film that is capable of improving the package reliability by preventing damage of a semiconductor chip due to pressure during die bonding of the film having a configuration where a filler is not practically added, preventing a decrease of tensile storage modulus and preventing generation of warping due to heat shrinkage during thermosetting, and to provide an adhesive film with a dicing film in which the thermosetting adhesive film and the dicing film are laminated.

The present inventors have investigated a thermosetting adhesive film in order to solve the conventional problems. As a result, they have found that the object could be achieved by adopting the following configuration, and the present invention has been completed.

That is, the thermosetting adhesive film according to the present invention is a thermosetting adhesive film used at the time of manufacturing a semiconductor device and has a tensile storage modulus at 260° C. after thermosetting of 2×10⁵ to 5×10⁷ Pa, a content of a filler of 0.1% by weight or less based on the entire thermosetting adhesive film, and a thickness of 1 to 10 μm.

According to the above-described configuration, the tensile storage modulus at 260° C. after thermosetting is 2×10⁵ to 5×10⁷ Pa and the decrease of the tensile storage modulus is suppressed even though the content of a filler is 0.1% by weight or less based on the entire thermosetting adhesive film and the film has a configuration where the film does not substantially contain a filler. Further, the absolute amount of deformation due to heat shrinkage can be minimized because the thickness of the film is relatively thin, being 1 to 10 μm. Especially, when the film is used as a die-bonding film, the generation of stress due to pressure during die bonding can be suppressed according to the above-described configuration because the content of a filler is 0.1% by weight or less based on the entire thermosetting adhesive film and the film has a configuration where the film does not substantially contain a filler. Excellent solder reflow resistance, etc. can be obtained and the package reliability of a semiconductor device to be manufactured can be improved because the tensile storage modulus at 260° C. after thermosetting is relatively high, being 2×10⁵ to 5×10⁷ Pa. Further, not only the absolute amount of deformation due to heat shrinkage can be minimized, but also the stress can be made to be small even if there is deformation because the thickness of the film is relatively thin, being 1 to 10 μm. As a result, warping of a semiconductor chip can be prevented.

As described above, according to the configuration, the reliability of the package can be improved because the generation of stress due to existence of a filler is suppressed with the configuration where the film does not substantially contain a filler, and warping of the semiconductor chip is prevented by making the tensile storage modulus relatively high and the thickness of the film thin.

In the configuration, the film preferably has a glass transition temperature before thermosetting of 15 to 50° C. By making the glass transition temperature before thermosetting 15° C. or more, the tensile storage modulus can be improved, and by making the temperature 50° C. or less, adhesion of the thermosetting adhesive film to a semiconductor wafer can be improved.

In the configuration, the film contains an acrylic resin, and the acrylic resin preferably has a glass transition temperature of −15 to 15° C. By making the glass transition temperature of the acrylic resin −15° C. or more, the tensile storage modulus of the thermosetting adhesive film can be further improved, and by making the temperature 15° C. or less, adhesion of the thermosetting adhesive film to a semiconductor wafer can be further improved.

In the configuration, the film contains an epoxy resin, a phenol resin, and an acrylic resin, and preferably has B/(A+B) of 0.15 to 0.95, where A represents a total weight of the epoxy resin, the phenol resin, and the acrylic resin and B represents a weight of the acrylic resin. By making B/(A+B) 0.15 to 0.95, a film that functions as an adhesive film can be formed.

In the configuration, the film preferably has an amount of warping after thermosetting of 100 μm or less. By making the amount of warping after thermosetting 100 μm or less, the generation of damage due to warping of a semiconductor chip can be suppressed.

In the configuration, the film preferably has a shear adhering strength to a silicon substrate before thermosetting of 0.04 to 2 MPa under a condition of 175° C. By making the shear adhering strength 0.04 MPa or more, the generation of shear deformation at the adhesion surface with a semiconductor chip due to ultrasonic vibration or heating in a wire bonding step can be made small.

In the configuration, the film preferably has a surface roughness before thermosetting of 50 nm or less. By making the surface roughness before thermosetting is 50 nm or less, the generation of damage to a semiconductor chip during a die bonding step can be suppressed.

In the configuration, the film preferably has a tensile storage modulus at 120° C. before thermosetting of 1×10⁴ to 2.5×10⁶ Pa. By making the tensile storage modulus 1×10⁴ Pa or more, the generation of shear deformation at the adhesion surface with a semiconductor chip can be made small.

Further, the adhesive film with a dicing film according to the present invention includes the thermosetting adhesive film laminated on the dicing film in order to solve the above problems.

In the configuration, the thermosetting adhesive film preferably has a peeling strength of 0.005 to 0.2 N/20 mm from the dicing film. By making the peeling strength 0.005 N/20 mm or more, the thermosetting adhesive film can be prevented from peeling from the dicing film during dicing. By making the strength 0.2 N/20 mm or less, a semiconductor chip can be picked up easily.

The method of manufacturing a semiconductor device according to the present invention is a method of manufacturing a semiconductor device using the thermosetting adhesive film or the adhesive film with a dicing film and is a method wherein a die bonding temperature is 80 to 150° C., a die bonding pressure is 0.05 to 5 MPa, and a die bonding time is 0.1 to 5 seconds in a die bonding step in which a semiconductor chip is die-bonded to an adherend through the thermosetting adhesive film interposed therebetween.

Because the thermosetting adhesive film has a configuration where the content of a filler is 0.1% by weight or less based on the entire thermosetting adhesive film and where the film does not substantially contain a filler, the generation of stress due to pressure under a condition of a die bonding pressure of 0.05 to 5 MPa can be suppressed. Further, because the thickness of the thermosetting adhesive film is relatively thin, being 1 to 10 μm, and heat is easily conducted into the entire thermosetting adhesive film, the die bonding temperature can be made relatively low, being 80 to 150° C., and the die bonding time can be made relatively short, being 0.1 to 5 seconds. As a result, manufacturing efficiency of a semiconductor device can be improved.

### BRIEF DESCRIPTION OF THE DRAWINGS

FIG. 1 is a sectional schematic view showing an adhesive film with a dicing film according to one embodiment of the present invention;

FIG. 2 is a sectional schematic view showing an adhesive film with a dicing film according to another embodiment of the present invention; and

FIG. 3 is a sectional schematic view for illustrating one method of manufacturing a semiconductor device according to the present embodiment.

### DETAILED DESCRIPTION OF THE PREFERRED EMBODIMENTS

### Adhesive Film with Dicing Film

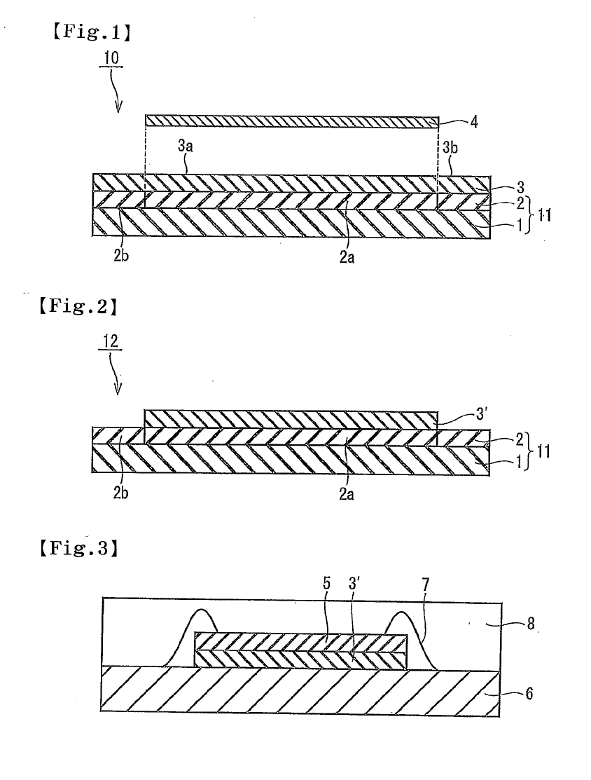

An adhesive film with a dicing film according to one embodiment of the present invention is described hereinbelow. FIG. 1 is a sectional schematic view showing an adhesive film with a dicing film according to one embodiment of the present invention. FIG. 2 is a sectional schematic view showing an adhesive film with a dicing film according to another embodiment of the present invention.

As shown in FIG. 1, an adhesive film with a dicing film 10 has a configuration in which an adhesive film 3 is laminated on a dicing film 11. The dicing film 11 is configured by laminating a pressure-sensitive adhesive layer 2 on a base material 1, and the adhesive film 3 is provided on the pressure-sensitive adhesive layer 2. Further, the present invention may also have a configuration in which an adhesive film 3′ is formed only on a work piece pasting portion as an adhesive film with a dicing film 12 shown in FIG. 2.

Moreover, the adhesive film of the present invention (thermosetting adhesive film) may be used as a single body of an adhesive film with no dicing film or may be used in a form of an adhesive film with a dicing film. Further, in the present invention, the adhesive film can be used as a die-bonding film or a wafer backside protecting film. The wafer backside protecting film is used to protect the backside of a semiconductor chip (exposed surface on the opposite side of a substrate) when mounting the semiconductor chip on the substrate by flip chip bonding.

The base material 1 is a base body for strength of the adhesive films with a dicing film 10 and 12, and preferably has ultraviolet-ray permeability. Examples thereof include polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinylacetate copolymer; an ionomer resin; an ethylene (meth)acrylic acid copolymer; an ethylene (meth)acrylic acid ester (random or alternating) copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; whole aromatic polyamides; polyphenylsulfide; aramid (paper); glass; glass cloth; a fluorine resin; polyvinyl chloride; polyvinylidene chloride; a cellulose resin; a silicone resin; metal (foil); and paper.

An example of a material of the base material 1 is a polymer such as a cross-linked body of the resins described above. The plastic films may be used in a non-stretched state or may be used in a uniaxially or biaxially stretched state as necessary. With a resin sheet to which a heat shrinking property is imparted by a stretching treatment or the like, the adhering area of the pressure-sensitive adhesive layer 2 to the adhesive films 3 and 3′ can be reduced by heat-shrinking the base material 1 after dicing, and the semiconductor chips can be collected easily.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of the base material 1 in order to improve adhesiveness, holding properties, etc. with the adjacent layer.

The thickness of the base material 1 can be appropriately decided without limitation particularly. However, it is generally about 5 to 200 μm.

The pressure-sensitive adhesive used for the formation of the pressure-sensitive adhesive layer 2 is not especially limited, and general pressure-sensitive adhesives such as an acrylic pressure-sensitive adhesive and a rubber pressure-sensitive adhesive can be used. An acrylic pressure-sensitive adhesive containing an acrylic polymer as a base polymer is preferable as the pressure-sensitive adhesive from the viewpoint of cleaning and washing properties of an electronic part such as a semiconductor wafer or a glass part that dislike contamination with ultrapure water or an organic solvent such as alcohol.

Specific examples of the acrylic ester include an acryl polymer in which acrylate is used as a main monomer component. Examples of the acrylate include alkyl acrylate (for example, a straight chain or branched chain alkyl ester having 1 to 30 carbon atoms, and particularly 4 to 18 carbon atoms in the alkyl group such as methylester, ethylester, propylester, isopropylester, butylester, isobutylester, sec-butylester, t-butylester, pentylester, isopentylester, hexylester, heptylester, octylester, 2-ethylhexylester, isooctylester, nonylester, decylester, isodecylester, undecylester, dodecylester, tridecylester, tetradecylester, hexadecylester, octadecylester, and eicosylester) and cycloalkyl acrylate (for example, cyclopentylester, cyclohexylester, etc.). These monomers may be used alone or two or more types may be used in combination. All of the words including “(meth)” in connection with the present invention have an equivalent meaning.

The acrylic polymer may optionally contain a unit corresponding to a different monomer component copolymerizable with the above-mentioned alkyl ester of (meth)acrylic acid or cycloalkyl ester thereof in order to improve the cohesive force, heat resistance or some other property of the polymer. Examples of such a monomer component include carboxyl-containing monomers such as acrylic acid, methacrylic acid, carboxyethyl (meth)acrylate, carboxypentyl (meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxylmethylcyclohexyl)methyl (meth)acrylate; sulfonic acid group containing monomers such as styrenesulfonic acid, allylsulfonic acid, 2-(meth)acrylamide-2-methylpropanesulfonic acid, (meth)acrylamidepropanesulfonic acid, sulfopropyl (meth)acrylate, and (meth)acryloyloxynaphthalenesulfonic acid; phosphoric acid group containing monomers such as 2-hydroxyethylacryloyl phosphate; acrylamide; and acrylonitrile. These copolymerizable monomer components may be used alone or in combination of two or more thereof. The amount of the copolymerizable monomer(s) to be used is preferably 40% or less by weight of all the monomer components.

For crosslinking, the acrylic polymer can also contain multifunctional monomers if necessary as the copolymerizable monomer component. Such multifunctional monomers include hexane dioldi(meth)acrylate, (poly)ethyleneglycoldi(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy (meth)acrylate, polyester (meth)acrylate, urethane (meth)acrylate etc. These multifunctional monomers can also be used as a mixture of one or more thereof. From the viewpoint of adhesiveness etc., the use amount of the multifunctional monomer is preferably 30 wt % or less based on the whole monomer components.

Preparation of the above acryl polymer can be performed by applying an appropriate manner such as a solution polymerization manner, an emulsion polymerization manner, a bulk polymerization manner, and a suspension polymerization manner to a mixture of one or two or more kinds of component monomers for example. Since the pressure-sensitive adhesive layer preferably has a composition in which the content of low molecular weight materials is suppressed from the viewpoint of prevention of wafer contamination, and since those in which an acryl polymer having a weight average molecular weight of 300000 or more, particularly 400000 to 30000000 is as a main component are preferable from such viewpoint, the pressure-sensitive adhesive can be made to be an appropriate cross-linking type with an internal cross-linking manner, an external cross-linking manner, etc.

An external crosslinking agent can be appropriately adopted in the pressure-sensitive adhesive to increase the number average molecular weight of the acrylic polymer or the like that is the base polymer. Specific examples of an external crosslinking method include a method of adding a so-called crosslinking agent such as a polyisocyanate compound, an epoxy compound, an aziridine compound, or a melamine crosslinking agent and reacting the product. When the external crosslinking agent is used, the used amount is appropriately determined by a balance with the base polymer to be crosslinked and further by the use as the pressure-sensitive adhesive. Generally, it is about 5 parts by weight or less, and preferably 0.1 to 5 parts by weight to 100 parts by weight of the base polymer. Further, conventionally known various additives such as a tackifier and an antioxidant may be used in the pressure-sensitive adhesive other than the above-described components as necessary.

The pressure-sensitive adhesive layer 2 can be formed with a radiation curing-type pressure-sensitive adhesive. The adhesive strength of the radiation curing-type pressure-sensitive adhesive can be reduced easily by increasing the degree of crosslinking by irradiation with an ultraviolet ray or the like, and a difference in the adhesive strength with the portion 2b may be created by irradiating with an ultraviolet ray only the portion 2a that corresponds to the work piece pasting portion of the pressure-sensitive adhesive layer 2 shown in FIG. 2.

The portion 2a where the adhesive strength is remarkably reduced can be easily formed by curing the radiation curing-type pressure-sensitive adhesive layer 2 in accordance with the adhesive film 3′ shown in FIG. 2. Because the adhesive film 3′ is pasted onto the portion 2a where the adhesive strength is reduced by curing, the interface between the portion 2a in the pressure-sensitive adhesive layer 2 and the adhesive film 3′ has a characteristic of peeling easily during pickup. On the other hand, the portion that is not irradiated with radiation has sufficient adhesive strength and forms the portion 2b.

As described above, the portion 2b that is formed with an uncured radiation curing-type pressure-sensitive adhesive adheres to the adhesive film 3, and the holding power can be secured during dicing in the pressure-sensitive adhesive layer 2 of the adhesive film with a dicing film 10 shown in FIG. 1.

As described above, the radiation curable pressure-sensitive adhesive can support the adhesive film 3 for fixing a chip-shaped work piece such as a semiconductor chip onto an adherend such as a substrate with a good balance of adhering and peeling. In the pressure-sensitive adhesive layer 2 of the adhesive film with a dicing film 12 shown in FIG. 2, the portion 2b can fix a wafer ring.

As the radiation curing-type pressure-sensitive adhesive, those having a radiation curable functional group such as a carbon-carbon double bond and having adherability can be used without particular limitation. An example of the radiation curing-type pressure-sensitive adhesive is an adding-type radiation curing-type pressure-sensitive adhesive in which a radiation curable monomer or oligomer component is incorporated into a general pressure-sensitive adhesive such as the acrylic pressure-sensitive adhesive or the rubber pressure-sensitive adhesive.

Examples of the radiation curing-type monomer component to be compounded include such as an urethane oligomer, urethane (meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane dioldi(meth)acrylate. Further, the radiation curing-type oligomer component includes various types of oligomers such as an urethane based, a polyether based, a polyester based, a polycarbonate based, and a polybutadiene based oligomer, and its molecular weight is appropriately in a range of about 100 to 30,000. The compounding amount of the radiation curing-type monomer component and the oligomer component can be appropriately determined to an amount in which the adhesive strength of the pressure-sensitive adhesive layer can be decreased depending on the type of the pressure-sensitive adhesive layer. Generally, it is for example 5 to 500 parts by weight, and preferably about 40 to 150 parts by weight based on 100 parts by weight of the base polymer such as an acryl polymer constituting the pressure sensitive adhesive.

Further, besides the added type radiation curing-type pressure-sensitive adhesive described above, the radiation curing-type pressure-sensitive adhesive includes an internal radiation curing-type pressure-sensitive adhesive using an acryl polymer having a radical reactive carbon-carbon double bond in the polymer side chain, in the main chain, or at the end of the main chain as the base polymer. The internal radiation curing-type pressure-sensitive adhesives of an internally provided type are preferable because they do not have to contain the oligomer component, etc. that is a low molecular weight component, or most of them do not contain, they can form a pressure-sensitive adhesive layer having a stable layer structure without migrating the oligomer component, etc. in the pressure sensitive adhesive over time.

The above-mentioned base polymer, which has a carbon-carbon double bond, may be any polymer that has a carbon-carbon double bond and further has viscosity. As such a base polymer, a polymer having an acrylic polymer as a basic skeleton is preferable. Examples of the basic skeleton of the acrylic polymer include the acrylic polymers exemplified above.

The method for introducing a carbon-carbon double bond into any one of the above-mentioned acrylic polymers is not particularly limited, and may be selected from various methods. The introduction of the carbon-carbon double bond into a side chain of the polymer is easier in molecule design. The method is, for example, a method of copolymerizing a monomer having a functional group with an acrylic polymer, and then causing the resultant to condensation-react or addition-react with a compound having a functional group reactive with the above-mentioned functional group and a carbon-carbon double bond while keeping the radiation curability of the carbon-carbon double bond.

Examples of the combination of these functional groups include a carboxylic acid group and an epoxy group; a carboxylic acid group and an aziridine group; and a hydroxyl group and an isocyanate group. Of these combinations, the combination of a hydroxyl group and an isocyanate group is preferable from the viewpoint of the easiness of reaction tracing. If the above-mentioned acrylic polymer, which has a carbon-carbon double bond, can be produced by the combination of these functional groups, each of the functional groups may be present on any one of the acrylic polymer and the above-mentioned compound. It is preferable for the above-mentioned preferable combination that the acrylic polymer has the hydroxyl group and the above-mentioned compound has the isocyanate group. Examples of the isocyanate compound in this case, which has a carbon-carbon double bond, include methacryloyl isocyanate, 2-methacryloyloxyethyl isocyanate, and m-isopropenyl-α,α-dimethylbenzyl isocyanate. The used acrylic polymer may be an acrylic polymer copolymerized with any one of the hydroxyl-containing monomers exemplified above, or an ether compound such as 2-hydroxyethyl vinyl ether, 4-hydroxybutyl vinyl ether or diethylene glycol monovinyl ether.

The intrinsic type radiation curable adhesive may be made only of the above-mentioned base polymer (in particular, the acrylic polymer), which has a carbon-carbon double bond. However, the above-mentioned radiation curable monomer component or oligomer component may be incorporated into the base polymer to such an extent that properties of the adhesive are not deteriorated. The amount of the radiation curable oligomer component or the like is usually 30 parts or less by weight, preferably from 0 to 10 parts by weight for 100 parts by weight of the base polymer.

The radiation curing-type pressure-sensitive adhesive preferably contains a photopolymerization initiator in the case of curing it with an ultraviolet ray or the like Examples of the photopolymerization initiator include α-ketol compounds such as 4-(2-hydroxyethoxy)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, and anisoin methyl ether; ketal compounds such as benzyl dimethyl ketal; aromatic sulfonyl chloride compounds such as 2-naphthalenesulfonyl chloride; optically active oxime compounds such as 1-phenone-1,1-propanedione-2-(o-ethoxycarbonyl)oxime; benzophenone compounds such as benzophenone, benzoylbenzoic acid, and 3,3′-dimethyl-4-methoxybenzophenone; thioxanthone compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphonoxides; and acylphosphonates. The amount of the photopolymerization initiator to be blended is, for example, from about 0.05 to 20 parts by weight for 100 parts by weight of the acrylic polymer or the like which constitutes the adhesive as a base polymer.

Further, examples of the radiation curing-type pressure-sensitive adhesive which is used in the formation of the pressure-sensitive adhesive layer 2 include such as a rubber pressure-sensitive adhesive or an acryl pressure-sensitive adhesive which contains an addition-polymerizable compound having two or more unsaturated bonds, a photopolymerizable compound such as alkoxysilane having an epoxy group, and a photopolymerization initiator such as a carbonyl compound, an organic sulfur compound, a peroxide, an amine, and an onium salt compound, which are disclosed in JP-A No. 60-196956. Examples of the above addition-polymerizable compound having two or more unsaturated bonds include such as polyvalent alcohol ester or oligoester of acryl acid or methacrylic acid and an epoxy or a urethane compound.

The radiation curing-type pressure-sensitive adhesive layer 2 can contain a compound that is colored by radiation irradiation as necessary. By containing the compound that is colored by radiation irradiation in the pressure-sensitive adhesive layer 2, only a portion irradiated with radiation can be colored. That is, the portion 2a that corresponds to the work piece pasting portion 3a shown in FIG. 1 can be colored. Therefore, whether the pressure-sensitive adhesive layer 2 is irradiated with radiation or not can be visually determined right away, and the work piece pasting portion 3a can be recognized easily, and the pasting of the work piece is easy. Further, when detecting a semiconductor element with a photosensor or the like, the detection accuracy improves, and no false operation occurs during pickup of the semiconductor element.

The compound that colors by radiation irradiation is colorless or has a pale color before the irradiation. However, it is colored by irradiation with radiation. A preferred specific example of the compound is a leuco dye. Common leuco dyes such as triphenylmethane, fluoran, phenothiazine, auramine, and spiropyran dyes can be preferably used. Specific examples thereof include 3-[N-(p-tolylamino)]-7-anilinofluoran, 3-[N-(p-tolyl)-N-methylamino]-7-anilinofluoran, 3-[N-(p-tolyl)-N-ethylamino]-7-anilinofluoran, 3-diethylamino-6-methyl-7-anilinofluoran, crystal violet lactone, 4,4′,4″-trisdimethylaminotriphenylmethanol, and 4,4′,4″-trisdimethylaminotriphenylmethane.

Examples of a developer that is preferably used with these leuco dyes include a prepolymer of a conventionally known phenolformalin resin, an aromatic carboxylic acid derivative, and an electron acceptor such as activated white earth, and various color developers can be used in combination for changing the color tone.

The compound that colors by irradiation with radiation may be included in the radiation curing-type pressure-sensitive adhesive after being dissolved in an organic solvent or the like, or may be included in the pressure-sensitive adhesive in the form of a fine powder. The ratio of use of this compound is 10% by weight or less, preferably 0.01 to 10% by weight, and more preferably 0.5 to 5% by weight in the pressure-sensitive adhesive layer 2. When the ratio of the compound exceeds 10% by weight, the curing of the portion 2a of the pressure-sensitive adhesive layer 2 becomes insufficient because the radiation onto the pressure-sensitive adhesive layer 2 is absorbed too much by this compound, and the adhesive strength may not reduce sufficiently. On the other hand, the ratio of the compound is preferably 0.01% by weight or more to color the compound sufficiently.

When forming the pressure-sensitive adhesive layer 2 with the radiation curing-type pressure-sensitive adhesive, part of the pressure-sensitive adhesive layer 2 may be irradiated with radiation so that the adhesive strength of the portion 2a in the pressure-sensitive adhesive layer 2 becomes less than the adhesive strength of the portion 2b.

An example of the method of forming the portion 2a on the pressure-sensitive adhesive layer 2 is a method of forming the radiation curing-type pressure-sensitive adhesive layer 2 on the base material 1 and then curing the layer by irradiating the portion 2a partially with radiation. The partial irradiation with radiation can be performed through a photo mask that has a pattern corresponding to the portion 3b or the like other than the work piece pasting portion 3a. Another example is a method of curing the layer by irradiation with an ultraviolet ray in spots. The formation of the radiation curing-type pressure-sensitive adhesive layer 2 can be performed by transferring a layer provided on a separator onto the base material 1. The partial radiation curing can also be performed on the radiation curing-type pressure-sensitive adhesive layer 2 that is provided on the separator.

Further, when forming the pressure-sensitive adhesive layer 2 with a radiation curing-type pressure-sensitive adhesive, the portion 2a having a reduced adhesive strength can be formed by using at least one surface of the base material 1 where the whole or part of the portion other than the portion corresponding to the work piece pasting portion 3a is protected from light, forming the radiation curing-type pressure-sensitive adhesive layer 2 on this surface, and curing the portion corresponding to the work piece pasting portion 3a by irradiation with radiation. As a light-shielding material, a material that is capable of serving as a photo mask on a supporting film can be produced by printing, vapor deposition, or the like. According to such a manufacturing method, the adhesive film with a dicing film 10 of the present invention can be efficiently manufactured.

When curing is inhibited due to oxygen during irradiation with radiation, it is desirable to shield oxygen (air) from the surface of the radiation curing-type pressure-sensitive adhesive layer 2 in some way. Examples of the method include a method of covering the surface of the pressure-sensitive adhesive layer 2 with a separator and a method of performing irradiation with an ultraviolet ray or the like in a nitrogen gas atmosphere.

The thickness of the pressure-sensitive adhesive layer 2 is not especially limited. However, it is preferably about 1 to 50 μm from the viewpoint of preventing cracking on the cut surface of the chip and maintaining the fixation of the adhesive layer. It is more preferably 2 to 30 μm, and further preferably 5 to 25 μm.

The content of a filler in the adhesive films 3 and 3′ is 0.1% by weight or less based on the entire adhesive films 3 and 3′, and it is preferable that no filler is contained (0% by weight). Examples of the filler include, but are not especially limited to, inorganic fillers such as aluminum hydroxide, magnesium hydroxide, calcium hydroxide, antimony trioxide, calcium carbonate, magnesium carbonate, calcium silicate, magnesium silicate, calcium oxide, magnesium oxide, aluminumoxide, aluminumnitride, aluminumborate, boron nitride, crystalline silica, and amorphous silica. The content (% by weigh) of a filler in the adhesive films 3 and 3′ can be obtained as an ash content (% by weight) hereinbelow.

In the measurement of an ash content, first, 1 g of the adhesive films 3 and 3′ are weighed into a crucible. The crucible used is baked at 50° C. for 2 hours and then cooled at room temperature in advance. Next, the weighed adhesive films 3 and 3′ are burnt with a burner until the smoke becomes invisible, and then made into ash by baking at 750° C. for 4 hours in an electric furnace. Then, after cooling to room temperature, the ash remaining in the crucible is weighed. The ash content is obtained from the weights of the adhesive films 3 and 3′ before and after ashing.

(Ash content(% by weight))=(Weight after ashing)/(Weight before ashing)×100

The adhesive film 3 and 3′ have a tensile storage modulus at 260° C. after thermosetting of 2.0×10⁵ to 5.0×10⁷ Pa, preferably 2.2×10⁵ to 4.8×10⁷ Pa, and more preferably 2.5×10⁵ to 4.6×10⁷ Pa. By making the tensile storage modulus 2.0×10⁵ Pa or more, the solder reflow resistance can be improved, and by making the tensile storage modulus 5.0×10⁷ Pa or less, good exhibition of the function as an adhesive film can be achieved. A heating condition when thermosetting the adhesive films 3 and 3′ will be described in detail later.

The adhesive films 3 and 3′ have a glass transition temperature (Tg) before thermosetting of 15 to 50° C., preferably 16 to 48° C., and more preferably 18 to 45° C. By making the temperature 15° C. or more, the tensile storage modulus of the adhesive films 3 and 3′ can be improved, and by making the temperature 50° C. or less, adhesion of the adhesive films 3 and 3′ to a semiconductor wafer 4 can be improved. The glass transition temperature can be measured according to a method described in the examples.

The adhesive films 3 and 3′ preferably have an amount of warping after thermosetting of 100 μm or less, more preferably 80 μm or less, and further preferably 60 μm or less. By making the amount 100 μm or less, the generation of damage due to warping of a semiconductor chip 5 can be suppressed. Moreover, the amount of warping can be measured according to a method described in the examples.

The adhesive films 3 and 3′ preferably have a surface roughness (Ra) before thermosetting of 50 nm or less, more preferably 45 nm or less, and further preferably 40 nm or less. By making the surface roughness 50 nm or less, the generation of damage to the semiconductor chip 5 during a die bonding step can be suppressed.

The adhesive films 3 and 3′ preferably have a tensile storage modulus at 120° C. before thermosetting of 1×10⁴ to 2.5×10⁶ Pa, more preferably 5×10⁴ to 2.5×10⁶ Pa, and further preferably 1×10⁵ to 2.5×10⁶ Pa. When the tensile storage modulus is 1×10⁴ Pa or more, the generation of shear deformation at the adhesion surface of the adhesive films 3 and 3′ with the semiconductor chip 5 can be made small.

The adhesive films 3 and 3′ preferably have a peeling strength of 0.005 to 0.2 N/20 mm from the dicing film 11, more preferably 0.01 to 0.18N/20 mm, and further preferably 0.02 to 0.16 N/20 mm. By making the strength 0.005 N/20 mm or more, the adhesive films 3 and 3′ can be prevented from peeling from the dicing film 11 during dicing. By making the strength 0.2 N/20 mm or less, the semiconductor chip 5 can be picked up easily. Moreover, the peeling strength of the adhesive films 3 and 3′ from the dicing film 11 can be measured according to a method described in the examples.

The lamination structure of the adhesive films 3 and 3′ is not especially limited, and examples thereof include a structure consisting of a single layer of a adhesive film and a multi-layer structure in which adhesive layer(s) is/are formed on one surface or both surfaces of a core material. Examples of the core material include films (such as polyimide film, polyester film, polyethylene terephthalate film, polyethylene naphthalate film, and polycarbonate film); resin substrates which are reinforced with glass fiber or plastic nonwoven finer; silicon substrates; and glass substrates.

Example of an adhesive composition constituting the adhesive films 3 and 3′ include those in which a thermoplastic resin and a thermosetting resin are used together. Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon and 6,6-nylon, phenoxy resin, acrylic resin, saturated polyester resins such as PET and PBT, polyamideimide resin, and fluorine-contained resin. These thermoplastic resins may be used alone or in combination of two or more thereof. Of these thermoplastic resins, acrylic resin is particularly preferable since the resin contains ionic impurities in only a small amount and has a high heat resistance so as to make it possible to ensure the reliability of the semiconductor element.

The acrylic resin is not limited to any especial kind, and may be, for example, a polymer comprising, as a component or components, one or more esters of acrylic acid or methacrylic acid having a linear or branched alkyl group having 30 or less carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

Among the acrylic resins, those preferably have a weight average molecular weight of 100,000 or more, more preferably 300,000 to 3,000,000, and further preferably 500,000 to 2,000,000. When the weight average molecular weight is within the above range, the tackiness and the heat resistance become excellent. The weight average molecular weight is a value that is measured by GPC (gel permeation chromatography) and calculated in terms of polystyrene.

The acrylic resin preferably has a glass transition temperature (Tg) of −15 to 15° C., more preferably −14 to 14° C., and further preferably −13 to 13° C. By making the temperature −15° C. or more, the tensile storage modulus of the adhesive films 3 and 3′ can be further improved, and by making the temperature 15° C. or less, adhesion of the adhesive films 3 and 3′ to the semiconductor wafer 4 can be further improved.

Two types or more of the acrylic resins having a different glass transition temperature may be used together. In this case, two type or more of the acrylic resins having a different functional group may be used together, two types or more of the acrylic resins having a different weight average molecular weight and the same functional group may be used together, or two types or more of the acrylic resins having a different functional group and a different weight average molecular weight may be used together.

A different monomer which constitutes the above-mentioned polymer is not limited to any especial kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl) methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl (meth)acrylate, and (meth)acryloyloxynaphthalenesulfonic acid; and monomers which contain a phosphoric acid group, such as 2-hydroxyethylacryloyl phosphate.

The blending ratio of the thermosetting resin is not especially limited as long as it is to an extent that the adhesive films 3 and 3′ can exhibit a function as a thermosetting resin when heating under a prescribed condition. However, it is preferably in the range of 5 to 60% by weight, and more preferably in the range of 10 to 50% by weight.

Examples of the above-mentioned thermosetting resin include phenol resin, amino resin, unsaturated polyester resin, epoxy resin, polyurethane resin, silicone resin, and thermosetting polyimide resin. These resins may be used alone or in combination of two or more thereof. Particularly preferable is epoxy resin, which contains ionic impurities which corrode semiconductor elements in only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly (p-oxystyrene). These may be used alone or in combination of two or more thereof. Among these phenol resins, phenol Novolak resin and phenol aralkyl resin are particularly preferable, since the connection reliability of the semiconductor device can be improved.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

Among the adhesive films 3 and 3′, adhesive films containing an epoxy resin, a phenol resin, and an acrylic resin and having B/(A+B) of 0.15 to 0.95 are preferable, where A represents a total weight of the epoxy resin, the phenol resin, and the acrylic resin and B represents a weight of the acrylic resin. By making B/(A+B) 0.15 to 0.95, a film that functions as an adhesive film can be formed.

When the adhesive films 3 and 3′ of the present invention are cross-linked at a certain level in advance, a multifunctional compound that reacts with a functional group at the ends of a molecular chain of a polymer, etc. is preferably added as a crosslinking agent at the time of producing the film. Accordingly, adhesion characteristics under high temperature can be improved and the heat resistance can be improved.

Conventionally known crosslinking agents can be adopted as the crosslinking agent. Especially, polyisocyanate compounds such as tolylene diisocyanate, diphenylmethane diisocyanate, p-phenylene diisocyanate, 1,5-naphthalene diisocyanate, and addition products of polyhydric alcohol and diisocyanate are more preferable. An amount of the crosslinking agent added is normally preferably 0.05 to 7 parts by weight based on 100 parts by weight of the polymer. It is because by making the amount of the crosslinking agent 0.05 parts by weight or more, cohesive strength can made to be sufficient, and by making the amount 7 parts by weight or less, adhering strength can be improved. Further, other multifunctional compounds such as an epoxy resin may be contained together with such polyisocyanate compounds depending on necessity.

Moreover, additives can be appropriately blended to the adhesive films 3 and 3′ depending on necessity. Examples of the additives include flame retardants, silane coupling agents, and ion trapping agents. Examples of the flame retardants include brominated epoxy resins. These can be used alone or two types or more of them can be used together. Examples of the silane coupling agents include β-(3,4-epoxycyclohexyl)ethyltrimethoxysilane, γ-glycidoxypropyltrimethoxysilane, and γ-glycidoxypropylmethyldiethoxysilane. These compounds can be used alone or two types or more of them can be used together. Examples of the ion trapping agents include chelating agents. These can be used alone or two types or more of them can be used together.

The thermal curing accelerator catalyst for the epoxy resin and the phenol resin is not especially limited, and it is appropriately selected from known thermal curing accelerator catalysts. The thermal curing accelerator catalyst can be used alone or two types or more of them can be used in combination. Examples of the thermal curing accelerator catalyst that can be used include an amine curing accelerator, a phosphorus curing accelerator, an imidazole curing accelerator, a boron curing accelerator, and a phosphorus-boron curing accelerator.

The adhesive films 3 and 3′ may be colored as necessary in the present invention. The color that is provided to the adhesive films 3 and 3′ by coloring is not especially limited, and preferred examples thereof include black, blue, red, and green. When the adhesive film is used as a die bond film, it is normally not colored (although it may be colored). However, when it is used as wafer backside protecting film, it is normally colored. For coloring, a colorant to be used can be appropriately selected from known colorants such as pigments and dyes.

The adhesive films 3 and 3′ (total thickness when they are a laminated body) have a thickness of 1 to 10 μm, preferably 2 to 10 μm, and more preferably 3 to 10 μm. By making the thickness 1 μm or more, the good film forming property of the adhesive films 3 and 3′ can be achieved. By making the thickness 10 μm or less, the absolute amount of deformation due to heat shrinkage can be minimized, and the stress can be made to be small even if there is deformation. As a result, warping of a semiconductor chip can be prevented. Further, by making the thickness 10 μm or less, an organic volatile component that remains in the adhesive films 3 and 3′ can be reduced and the solder reflow resistance can be improved.

The adhesive films 3, 3 of the adhesive film with a dicing films 10, 11 are preferably protected by a separator (not shown). The separator has a function as a protecting material that protects the adhesive films 3, 3′ until they are practically used. Further, the separator can be used as a supporting base material when transferring the adhesive films 3, 3′ to the pressure-sensitive adhesive layer 2. The separator is peeled when pasting a workpiece onto the adhesive films 3, 3′ of the adhesive film with a dicing film. Polyethylenetelephthalate (PET), polyethylene, polypropylene, a plastic film, a paper, etc. whose surface is coated with a peeling agent such as a fluorine based peeling agent and a long chain alkylacrylate based peeling agent can be also used as the separator.

The adhesive films with a dicing film 10 and 12 according to the present embodiment can be produced as follows for example.

First, the base material 1 can be formed with a conventionally known method of forming a film. Examples of a method of forming the base material 1 include a calender film forming method, a casting method in an organic solvent, an inflation extrusion method in a closed system, a T die extrusion method, a coextrusion method, and a dry lamination method.

Next, the pressure-sensitive adhesive layer 2 is formed by forming a coating film by applying a pressure-sensitive adhesive composition onto the base material 1 and then drying the coating film under a prescribed condition (heat cross-linking depending on necessity). The applying method is not especially limited, and examples thereof include roll coating, screen coating, and gravure coating. The drying is performed at a drying temperature of 80 to 150° C. and a drying time of 0.5 to 5 minutes. The pressure-sensitive adhesive layer 2 may be formed by forming a coating film by applying a pressure-sensitive adhesive composition onto a separator and then drying the coating film in the above drying condition. Thereafter, the pressure-sensitive adhesive layer 2 is pasted onto the base material 1 together with the separator. Accordingly, the dicing film 11 is produced.

The adhesive films 3 and 3′ are produced as follows for example.

First, an adhesive composition solution that is a material for forming the adhesive films with a dicing film 3 and 3′ is produced. The adhesive composition, various additives, etc. are blended in the adhesive composition solution as described above.

Next, an adhesive layer is formed by forming a coating film by applying the adhesive composition solution onto a base separator to have a prescribed thickness and then drying the coating film under a prescribed condition. The applying method is not especially limited, and examples thereof include roll coating, screen coating, and gravure coating. The drying is performed at a drying temperature of 70 to 160° C. and a drying time of 1 to 5 minutes. The adhesive layer may be formed by forming a coating film by applying a pressure-sensitive adhesive composition onto a separator and then drying the coating film in the above drying condition. Thereafter, the adhesive layer is pasted onto the base separator together with the separator.

Subsequently, each separator is peeled from the dicing film 11 and the adhesive layer, and both are pasted together so that the adhesive layer and the pressure-sensitive adhesive layer becomes a pasting surface. The pasting can be performed by press bonding. At this time, the laminating temperature is not especially limited. However, it is preferably 30 to 50° C. and more preferably 35 to 45° C. The linear pressure is not especially limited. However, it is preferably 0.1 to 20 kgf/cm and more preferably 1 to 10 kgf/cm. Next, the base separator on the adhesive layer is peeled to obtain the adhesive film with a dicing film according to the present embodiment.

### (Producing Method of Semiconductor Device)

The adhesive film with a dicing films 10, 11 of the present invention are used as follows by appropriately peeling the separator arbitrarily provided on the adhesive films 3, 3′. Hereinbelow, referring to FIG. 3, it is described while using the adhesive film with a dicing film 10 as an example.

First, a semiconductor wafer 4 is press-adhered on the adhesive film 3 in the adhesive film with a dicing film 10, and it is fixed by adhering and holding (mounting step). The present step is performed while pressing with a pressing means such as a pressing roll. At this time, the pasting temperature is preferably 35 to 80° C. and more preferably 40 to 75° C. The pressure is preferably 1×10⁵ to 1×10⁷ Pa and more preferably 2×10⁵ to 8×10⁶ Pa. The pasting time is preferably 1.5 to 60 seconds and more preferably 2 to 50 seconds.

Next, the dicing of the semiconductor wafer 4 is performed. Accordingly, the semiconductor wafer 4 is cut into a prescribed size and individualized, and a semiconductor chip 5 is produced. The dicing is performed following a normal method from the circuit face side of the semiconductor wafer 4, for example. Further, the present step can adopt such as a cutting method called full-cut that forms a slit in the adhesive film with a dicing film 10. The dicing apparatus used in the present step is not particularly limited, and a conventionally known apparatus can be used. Further, because the semiconductor wafer 4 is adhered and fixed by the adhesive film with a dicing film 10, chip crack and chip fly can be suppressed, and at the same time the damage of the semiconductor wafer can be also suppressed.

Pickup of the semiconductor chip 5 is performed in order to peel a semiconductor chip 5 that is adhered and fixed to the adhesive film with a dicing film 10. The method of picking up is not particularly limited. Examples include a method of pushing up the individual semiconductor chip 5 from the dicing die-bonding 10 side with a needle and picking up the pushed semiconductor chip 5 with a picking-up apparatus.

When the pressure-sensitive adhesive layer 2 is an ultraviolet-ray curing layer, pickup is performed after irradiating the pressure-sensitive adhesive layer 2 with ultraviolet-rays. Accordingly, the adhesive strength of the pressure-sensitive adhesive layer 2 to the adhesive layer 3 decreases, and the peeling of the semiconductor chip 5 becomes easy. As a result, picking up becomes possible without damaging the semiconductor chip 5. The condition such as irradiation intensity and irradiation time when irradiating an ultraviolet ray is not particularly limited, and it may be appropriately set depending on necessity. Further, the light source as described above can be used as a light source used in the ultraviolet irradiation.

The semiconductor chip 5 that is picked up is adhered and fixed onto an adherend 6 through the adhesive film 3 (die bonding) interposed therebetween.

At this time, the die bonding temperature is preferably 80 to 150° C., more preferably 85 to 140° C., and further preferably 90 to 130° C. By making the temperature 80° C. or more, the tensile storage modulus of the adhesive film 3 can be prevented from being too high, and good adhesion can be made possible. By making the temperature 150° C. or more, the generation of warping after die bonding can be prevented and the generation of damage can be suppressed.

Further, the die bonding pressure is preferably 0.05 to 5 MPa, more preferably 0.06 to 4.5 MPa, and further preferably 0.07 to 4 MPa. By making the pressure 0.05 MPa, the generation of uneven adhesion can be prevented. By making the pressure 5 MPa or less, the generation of damage to the semiconductor chip 5 due to pressure can be suppressed.

Furthermore, the die bonding time for which the die bonding pressure is applied is preferably 0.1 to 5 seconds, more preferably 0.15 to 4.5 seconds, and further preferably 0.2 to 4 seconds By making the time 0.1 second or more, the pressure can be applied uniformly, and the generation of uneven adhesion can be prevented. By making the time 5 seconds or less, the yield can be improved.

Examples of the adherend 6 include a lead frame, a TAB film, a substrate, and a semiconductor chip separately produced. The adherend 6 may be, for example, a deformable adherend that can be easily deformed or may be a non-deformable adherend that is difficult to be deformed such as a semiconductor wafer.

A conventionally known substrate can be used as the substrate. Further, a metal lead frame such as a Cu lead frame and a 42 Alloy lead frame and an organic substrate composed of glass epoxy, BT (bismaleimide-triazine), and polyimide can be used as the lead frame. However, the present invention is not limited to this, and includes a circuit substrate that can be used by mounting a semiconductor element and electrically connecting with the semiconductor element.

The thickness of the semiconductor wafer is not especially limited. However, it is 15 to 700 μm and more preferably 20 to 500 μm.

Then, the adhesive film 3 is thermally cured by performing a heat treatment, and the semiconductor chip 5 is adhered to the adherend 6. The condition of the heat treatment is a temperature of 80 to 180° C. and a heating time of 0.1 to 24 hours, preferably 0.1 to 4 hours, and more preferably 0.1 to 1 hour.

Next, a wire bonding step of electrically connecting the tip of a terminal part (inner lead) of the adherend 6 with an electrode pad (not shown) on the semiconductor chip 5 with a bonding wire 7 is performed. The bonding wires 7 may be, for example, gold wires, aluminum wires, or copper wires. The temperature when the wire bonding is performed is from 80 to 250° C., preferably from 80 to 220° C. The heating time is from several seconds to several minutes. The connection of the wires is performed by using a combination of vibration energy based on ultrasonic waves with compression energy based on the application of pressure in the state that the wires are heated to a temperature in the above-mentioned range.

Here, the adhesive film 3 preferably has a shear adhering strength to the adherend 6 after thermosetting of 0.1 MPa or more and more preferably 0.1 to 10 MPa. When the shear adhering strength of the adhesive film 3 is at least 0.1 MPa, the generation of shear deformation at the adhesion surface of the adhesive film 3 and the semiconductor chip 5 or the adherend 6 due to ultrasonic vibration and heating in a wire bonding step can be made small. That is, moving of a semiconductor element due to ultrasonic vibration during wire bonding can be remarkably decreased, and thereby, the success rate of wire bonding is prevented from decreasing.

Moreover, the wire bonding step may be performed without thermosetting the adhesive layer 3 by a heat treatment. In this case, the adhesive film 3 preferably has a shear adhering strength to the adherend 6 (silicon substrate) at 175° C. during temporary fixing (before thermosetting) of 0.04 to 2 Mpa, more preferably 0.6 to 2 Mpa and further preferably 0.1 to 2 MPa. When the shear adhering strength of the adhesive film 3 during temporary fixing is at least 0.04 MPa, the generation of shear deformation at the adhesion surface of the adhesive film 3 and the semiconductor chip 5 or the adherend 6 due to ultrasonic vibration and heating in the wire bonding step can be decreased even when the wire bonding step is performed without undergoing a heating step. That is, moving of a semiconductor element due to ultrasonic vibration during wire bonding can be remarkably decreased, and thereby, the success rate of wire bonding is prevented from decreasing.

Further, the uncured adhesive film 3 does not completely thermoset even when the wire bonding step is performed. The shear adhering strength of the adhesive film 3 is necessarily 0.04 MPa or more even when the temperature is within a range of 80 to 250° C. When the shear adhering strength is less than 0.04 MPa in this temperature range, the semiconductor element moves due to the ultrasonic vibration during wire bonding and the wire bonding cannot be performed, and therefore the yield decreases.

Then, a sealing step sealing the semiconductor chip 5 with a sealing resin 8 is performed. This step is performed for protecting the semiconductor chip 5 that is loaded on the adherend 6 and the bonding wire 7. This step is performed by molding a resin for sealing with a mold. An example of the sealing resin 8 is an epoxy resin. The heating temperature during the resin sealing is normally 175° C. and it is performed for 60 to 90 seconds. However, the present invention is not limited thereto, and the curing can be performed at 165 to 185° C. for a few minutes, for example. With this operation, the sealing resin is cured and the semiconductor chip 5 and the adherend 6 are fixed through the adhesive film 3 interposed therebetween. That is, in the present invention, even when a post curing step that described later is not performed, the adhesive film 3 can be thermally cured and adhered in this step and the present invention can contribute to a reduction in the number of manufacturing steps and a reduction in the manufacturing period of the semiconductor device.

Subsequently, the sealing resin 8 that is insufficiently cured in the sealing step is completely cured (post curing step). Even when the adhesive film 3 is not completely thermally cured in the sealing step, complete thermosetting of the adhesive film 3 together with the sealing resin 8 becomes possible in the present step. The heating temperature in this step differs depending on the type of the sealing resin. However, it is within a range of 165 to 185° C., for example, and the heating time is about 0.5 to 8 hours.

Further, the adhesive film with a dicing film of the present invention can be preferably used when three-dimensionally mounting a plurality of semiconductor chips by lamination. At this time, an adhesive film and a spacer may be laminated between the semiconductor chips or only the adhesive film may be laminated between the semiconductor chips without laminating the spacer. It can be changed appropriately depending on a manufacturing condition, use, etc.

Below, preferred examples of the present invention are explained in detail. However, materials, addition amounts, and the like described in these examples are not intended to limit the scope of the present invention, and are only examples for explanation as long as there is no description of limitation in particular. In addition, “part” means “parts by weight.”

### Example 1-1

An adhesive composition solution having a concentration of 23.6% by weight was obtained by dissolving the following (a) to (c) in methylethylketone.

(a) Epoxy resin (EPPN501HY manufactured by Nippon Kayaku Co., Ltd.) 283 parts by weight
(b) Phenol resin (MEH7851 manufactured by Meiwa Plastic Industries, Ltd.) 283 parts by weight
(c) Acrylic resin (Teisan Resin SG-70L manufactured by Nagase ChemteX Corporation, glass transition temperature: −13° C.) 100 parts by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Example 2-1

An adhesive composition solution having a concentration of 23.6% by weight was obtained by dissolving the following (a) to (c) in methylethylketone.

(a) Epoxy resin (EPPN501HY manufactured by Nippon Kayaku Co., Ltd.) 200 parts by weight
(b) Phenol resin (MEH7851 manufactured by Meiwa Plastic Industries, Ltd.) 200 parts by weight
(c) Acrylic resin (Teisan Resin SG-P3 manufactured by Nagase ChemteX Corporation, glass transition temperature: 12° C.) 100 parts by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Example 3-1

An adhesive composition solution having a concentration of 23.6% by weight was obtained by dissolving the following (a) to (c) in methylethylketone.

(a) Epoxy resin (EPPN501HY manufactured by Nippon Kayaku Co., Ltd.) 50 parts by weight
(b) Phenol resin (MEH7851 manufactured by Meiwa Plastic Industries, Ltd.) 50 parts by weight
(c) Acrylic resin (Paracron W-248 manufactured by Negami Chemical Industries Co., Ltd, glass transition temperature: 7° C.) 100 parts by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Example 4-1

An adhesive composition solution having a concentration of 23.6% by weight was obtained by dissolving the following (a) to (d) in methylethylketone.

(a) Epoxy resin (EPPN501HY manufactured by Nippon Kayaku Co., Ltd.) 21 parts by weight
(b) Phenol resin (MEH7851 manufactured by Meiwa Plastic Industries, Ltd.) 21 parts by weight
(c) Acrylic resin (Paracron W-248 manufactured by Negami Chemical Industries Co., Ltd, glass transition temperature: 7° C.) 100 parts by weight
(d) Crosslinking agent (Colonate L manufactured by Nippon Polyurethane Industry Co., Ltd.) 15 parts by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Example 5-1

An adhesive composition solution having a concentration of 23.6% by weight was obtained by dissolving the following (a) to (d) in methylethylketone.

(a) Epoxy resin (EPPN501HY manufactured by Nippon Kayaku Co., Ltd.) 12.5 parts by weight
(b) Phenol resin (MEH7851 manufactured by Meiwa Plastic Industries, Ltd.) 12.5 parts by weight
(c) Acrylic resin 1 (Teisan Resin SG-P3 manufactured by Nagase ChemteX Corporation, glass transition temperature: 12° C.) 50 parts by weight
(d) Acrylic resin 2 (Teisan Resin SG-70L manufactured by Nagase ChemteX Corporation, glass transition temperature: −13° C.) 50 parts by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Comparative Example 1-1

An adhesive composition solution having a concentration of 23.6% by weight was obtained by dissolving the following (a) to (c) in methylethylketone.

(a) Epoxy resin (EPPN501HY manufactured by Nippon Kayaku Co., Ltd.) 1 part by weight
(b) Phenol resin (MEH7851 manufactured by Meiwa Plastic Industries, Ltd.) 1 part by weight
(c) Acrylic resin (Arontack S-2060 manufactured by Toagosei Co., Ltd., glass transition temperature: −22° C.) 100 parts by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Comparative Example 2-1

An adhesive composition solution having a concentration of 23.6% by weight was obtained by dissolving the following (a) to (c) in methylethylketone.

(a) Epoxy resin (EPPN501HY manufactured by Nippon Kayaku Co., Ltd.) 50 parts by weight
(b) Phenol resin (MEH7851 manufactured by Meiwa Plastic Industries, Ltd.) 50 parts by weight
(c) Acrylic resin (Paracron W-197C manufactured by Negami Chemical Industries Co., Ltd, glass transition temperature: 18° C.) 1 part by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Comparative Example 3-1

An adhesive composition solution having a concentration of 23.6% by weight was obtained by dissolving the following (a) to (d) in methylethylketone.

(a) Epoxy resin (EPPN501HY manufactured by Nippon Kayaku Co., Ltd.) 283 parts by weight
(b) Phenol resin (MEH7851 manufactured by Meiwa Plastic Industries, Ltd.) 283 parts by weight
(c) Acrylic resin (Teisan Resin SG-70L manufactured by Nagase ChemteX Corporation, glass transition temperature: −13° C.) 100 parts by weight
(d) Spherical silica (SO-E2 manufactured by Admatechs Co., Ltd.) 10 parts by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Comparative Example 4-1

An adhesive composition solution having a concentration of 23.6% by weight was obtained by dissolving the following (a) to (d) in methylethylketone.

(a) Epoxy resin (EPPN501HY manufactured by Nippon Kayaku Co., Ltd.) 200 parts by weight
(b) Phenol resin (MEH7851 manufactured by Meiwa Plastic Industries, Ltd.) 200 parts by weight
(c) Acrylic resin (Arontack S-2060 manufactured by Toagosei Co., Ltd., glass transition temperature: −22° C.) 100 parts by weight
(d) Spherical silica (SO-E2 manufactured by Admatechs Co., Ltd.) 50 parts by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Comparative Example 5-1

An adhesive composition solution having a concentration of 23.6% by weight was obtained by dissolving the following (a) to (d) in methylethylketone.

(a) Epoxy resin (EPPN501HY manufactured by Nippon Kayaku Co., Ltd.) 4950 parts by weight
(b) Phenol resin (MEH7851 manufactured by Meiwa Plastic Industries, Ltd.) 4950 parts by weight
(c) Acrylic resin (Paracron W-248 manufactured by Negami Chemical Industries Co., Ltd, glass transition temperature: 7° C.) 100 parts by weight
(d) Spherical silica (SO-E2 manufactured by Admatechs Co., Ltd.) 25 parts by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Comparative Example 6-1

An adhesive composition solution having a concentration of 23.6% by weight was obtained by dissolving the following (a) to (d) in methylethylketone.

(a) Epoxy resin (EPPN501HY manufactured by Nippon Kayaku Co., Ltd.) 2450 parts by weight
(b) Phenol resin (MEH7851 manufactured by Meiwa Plastic Industries, Ltd.) 2450 parts by weight
(c) Acrylic resin (Paracron W-248 manufactured by Negami Chemical Industries Co., Ltd, glass transition temperature: 7° C.) 100 parts by weight
(d) Spherical silica (SO-E2 manufactured by Admatechs Co., Ltd.) 25 parts by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Comparative Example 7-1

An adhesive composition solution having a concentration of 23.6% by weight was obtained by dissolving the following (a) to (d) in methylethylketone.

(a) Epoxy resin (EPPN501HY manufactured by Nippon Kayaku Co., Ltd.) 12.5 parts by weight
(b) Phenol resin (MEH7851 manufactured by Meiwa Plastic Industries, Ltd.) 12.5 parts by weight
(c) Acrylic resin (Teisan Resin SG-P3 manufactured by Nagase ChemteX Corporation, glass transition temperature: 12° C.) 100 parts by weight
(d) Spherical silica (SO-E2 manufactured by Admatechs Co., Ltd.) 10 parts by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Comparative Example 8-1

An adhesive composition solution having a concentration of 23.6% by weight was obtained by dissolving the following (a) to (d) in methylethylketone.

(a) Epoxy resin (EPPN501HY manufactured by Nippon Kayaku Co., Ltd.) 6 parts by weight
(b) Phenol resin (MEH7851 manufactured by Meiwa Plastic Industries, Ltd.) 6 parts by weight
(c) Acrylic resin (Paracron W-248 manufactured by Negami

Chemical Industries Co., Ltd, glass transition temperature: 7° C.) 100 parts by weight

(d) Spherical silica (SO-E2 manufactured by Admatechs Co., Ltd.) 70 parts by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Comparative Example 9-1

An adhesive composition solution having a concentration of 23.6% by weight was obtained by dissolving the following (a) to (d) in methylethylketone.

(a) Epoxy resin (EPPN501HY manufactured by Nippon Kayaku Co., Ltd.) 2.6 parts by weight
(b) Phenol resin (MEH7851 manufactured by Meiwa Plastic Industries, Ltd.) 2.6 parts by weight
(c) Acrylic resin (Arontack S-2060 manufactured by Toagosei Co., Ltd., glass transition temperature: −22° C.) 100 parts by weight
(d) Spherical silica (SO-E2 manufactured by Admatechs Co., Ltd.). 20 parts by weight

An adhesive film having a thickness of 3 μm was produced by applying this adhesive composition solution onto a release-treated film (release liner) made of a polyethylene terephthalate film having a thickness of 38 μm on which a silicone release treatment was performed and by drying at 130° C. for 2 minutes.

### Example 1-2

An adhesive film according to the present example was produced in the same manner as in Example 1-1 except the thickness was changed to 5 μm in Example 1-2.

### Example 2-2

An adhesive film according to the present example was produced in the same manner as in Example 2-1 except the thickness was changed to 5 μm in Example 2-2.

### Example 3-2

An adhesive film according to the present example was produced in the same manner as in Example 3-1 except the thickness was changed to 5 μm in Example 3-2.

### Example 4-2

An adhesive film according to the present example was produced in the same manner as in Example 4-1 except the thickness was changed to 5 μm in Example 4-2.

### Example 5-2

An adhesive film according to the present example was produced in the same manner as in Example 5-1 except the thickness was changed to 5 μm in Example 5-2.

### Comparative Example 1-2

An adhesive film according to the present comparative example was produced in the same manner as in Comparative Example 1-1 except the thickness was changed to 5 μm in Comparative Example 1-2.

### Comparative Example 2-2

An adhesive film according to the present comparative example was produced in the same manner as in Comparative Example 2-1 except the thickness was changed to 5 μm in Comparative Example 2-2.

### Comparative Example 3-2

An adhesive film according to the present comparative example was produced in the same manner as in Comparative Example 3-1 except the thickness was changed to 5 μm in Comparative Example 3-2.

### Comparative Example 4-2

An adhesive film according to the present comparative example was produced in the same manner as in Comparative Example 4-1 except the thickness was changed to 5 μm in Comparative Example 4-2.

### Comparative Example 5-2

An adhesive film according to the present comparative example was produced in the same manner as in Comparative Example 5-1 except the thickness was changed to 5 μm in Comparative Example 5-2.

### Comparative Example 6-2

An adhesive film according to the present comparative example was produced in the same manner as in Comparative Example 6-1 except the thickness was changed to 5 μm in Comparative Example 6-2.

### Comparative Example 7-2

An adhesive film according to the present comparative example was produced in the same manner as in Comparative Example 7-1 except the thickness was changed to 5 μm in Comparative Example 7-2.

### Comparative Example 8-2

An adhesive film according to the present comparative example was produced in the same manner as in Comparative Example 8-1 except the thickness was changed to 5 μm in Comparative Example 8-2.

### Comparative Example 9-2

An adhesive film according to the present comparative example was produced in the same manner as in Comparative Example 9-1 except the thickness was changed to 5 μm in Comparative Example 9-2.

### Example 1-3

An adhesive film according to the present example was produced in the same manner as in Example 1-1 except the thickness was changed to 10 μm in Example 1-3.

### Example 2-3)

An adhesive film according to the present example was produced in the same manner as in Example 2-1 except the thickness was changed to 10 μm in Example 2-3.

### Example 3-3)

An adhesive film according to the present example was produced in the same manner as in Example 3-1 except the thickness was changed to 10 μm in Example 3-3.

### Example 4-3)

An adhesive film according to the present example was produced in the same manner as in Example 4-1 except the thickness was changed to 10 μm in Example 4-3.

### Example 5-3

An adhesive film according to the present example was produced in the same manner as in Example 5-1 except the thickness was changed to 10 μm in Example 5-3.

### Comparative Example 1-3

An adhesive film according to the present comparative example was produced in the same manner as in Comparative Example 1-1 except the thickness was changed to 10 μm in Comparative Example 1-3.

### Comparative Example 2-3

An adhesive film according to the present comparative example was produced in the same manner as in Comparative Example 2-1 except the thickness was changed to 10 μm in Comparative Example 2-3.

### Comparative Example 3-3

An adhesive film according to the present comparative example was produced in the same manner as in Comparative Example 3-1 except the thickness was changed to 10 μm in Comparative Example 3-3.

### Comparative Example 4-3

An adhesive film according to the present comparative example was produced in the same manner as in Comparative Example 4-1 except the thickness was changed to 10 μm in Comparative Example 4-3.

### Comparative Example 5-3

An adhesive film according to the present comparative example was produced in the same manner as in Comparative Example 5-1 except the thickness was changed to 10 μm in Comparative Example 5-3.

### Comparative Example 6-3

An adhesive film according to the present comparative example was produced in the same manner as in Comparative Example 6-1 except the thickness was changed to 10 μm in Comparative Example 6-3.

### Comparative Example 7-3

An adhesive film according to the present comparative example was produced in the same manner as in Comparative Example 7-1 except the thickness was changed to 10 μm in Comparative Example 7-3.

### Comparative Example 8-3

An adhesive film according to the present comparative example was produced in the same manner as in Comparative Example 8-1 except the thickness was changed to 10 μm in Comparative Example 8-3.

### Comparative Example 9-3

An adhesive film according to the present comparative example was produced in the same manner as in Comparative Example 9-1 except the thickness was changed to 10 μm in Comparative Example 9-3.

### Comparative Example 1-4

An adhesive film according to the present comparative example was produced in the same manner as in Example 1-1 except the thickness was changed to 25 μm in Comparative Example 1-4.

### Comparative Example 2-4

An adhesive film according to the present comparative example was produced in the same manner as in Example 2-1 except the thickness was changed to 25 μm in Comparative Example 2-4.

### Comparative Example 3-4

An adhesive film according to the present comparative example was produced in the same manner as in Comparative Example 3-1 except the thickness was changed to 25 mm in Comparative

### Example 3-4

The evaluations shown below were performed using the adhesive films that were obtained in the examples and comparative examples.

(Measurement of Tensile Storage Modulus at 260° C. after Thermosetting)

The obtained adhesive films were laminated to have a thickness of 100 μm under a condition of 40° C. and were thermally cured under a condition of 175° C. for 5 hours. Thereafter, the films were cut into rectangular measurement pieces each having a width of 10 mm. Next, the tensile storage modulus at −30 to 280° C. was measured under a condition of a frequency of 10 Hz and a temperature rising speed of 5° C./minute using a viscoelasticity measurement apparatus (RSA III manufactured by Rheometric Scientific, Ltd.). The measured values at 260° C. under the condition described above are shown in Tables 1 to 7.

### (Measurement of Glass Transition Temperature Before Thermosetting)

The obtained adhesive films were laminated to have a thickness of 100 μm under a condition of 40° C. and were cut into a rectangular measurement piece having a width of 10 mm. Next, the loss tangent (tan δ) at −30 to 280° C. was measured under a condition of a frequency of 10 Hz and a temperature rising speed of 5° C./minute using a viscoelasticity measurement apparatus (RSA III manufactured by Rheometric Scientific, Ltd.). The glass transition temperatures obtained from peak values of tan δ under the condition described above are shown in Tables 1 to 4.

(Measurement of Amount of Warping after Curing)

Each of the obtained adhesive films was pasted onto a semiconductor chip having a 10 mm square and a 50 μm thick at a temperature of 40° C. Then, the semiconductor chip was mounted on a resin substrate with a solder resist (glass epoxy substrate, thickness of substrate: 0.23 mm) through the adhesive film interposed therebetween. The condition at that time was such that the temperature was 120° C., the pressure was 0.2 MPa, and the time was 1 second. Next, the adhesive film was thermally cured by performing a heat treatment on the resin substrate on which the semiconductor chip was mounted at 175° C. for 5 hours in a dryer. Subsequently, the resin substrate was placed on a flat plate so that the resin substrate was the lower side, and unevenness on a diagonal line of the semiconductor chip was measured. Accordingly, the height of the semiconductor chip floating from the flat plate, that is the amount of warping (μm), was measured. In the measurement, both ends on the diagonal line of the semiconductor chip were equalized to be zero. The measurement was performed under a condition of a measurement speed of 1.5 mm/second and a load of 1 g using a surface roughness meter (DEKTAK 8 manufactured by Veeco Instruments). As a result of the measurement, a case where the amount of warping was more than 100 μm was marked as x, and a case where it was 100 μm or less was marked as ◯. The results are shown in Tables 1 to 7.

(Shear Adhering Strength with Silicon Substrate Before Curing)

Each of the obtained adhesive film was pasted onto a semiconductor chip having a 5 mm square and a 500 μm thick at a temperature of 40° C. Then, the semiconductor chip with the adhesive film was mounted on a silicon substrate under a die bonding condition such that the temperature was 120° C., the pressure was 0.1 MPa, and the time was 1 second. Thereafter, the shear adhering strength at 175° C. was measured. The results are shown in Tables 1 to 7.

### (Measurement of Surface Roughness of Adhesive Film)

The measurement of surface roughness was performed based on JIS B0601 using a non-contact three dimensional roughness meter (NT3300) manufactured by Veeco Instruments. Each of the measurement results was obtained by processing the measurement data with a median filter under a condition of 50 times. The results are shown in Tables 1 to 7.

### (Measurement of Tensile Storage Modulus at 120° C. Before Thermosetting)

The obtained adhesive films were laminated to have a thickness of 100 μm under a condition of 40° C. and were cut into rectangular measurement pieces each having a width of 10 mm. Next, the tensile storage modulus at −30 to 280° C. was measured under a condition of a frequency of 10 Hz and a temperature rising speed of 5° C./minute using a viscoelasticity measurement apparatus (RSA III manufactured by Rheometric Scientific, Ltd.). The values of the tensile storage modulus at 120° C. under the condition described above are shown in Tables 1 to 7.

(Measurement of Peeling Strength of Adhesive Film from Dicing Film)

First, a dicing film (DU-300 manufactured by Nitto Denko Corporation) was irradiated with ultraviolet rays using an ultraviolet-ray irradiation apparatus (UM-810 manufactured by Nitto Seiki Co., Ltd.). At this time, the ultraviolet-ray accumulative amount was set to be 300 mJ/cm².

Next, the dicing film irradiated with ultraviolet rays was pasted onto the obtained adhesive film at 40° C. and it was cut into a 20×20 mm piece. Next, the strength when the adhesive film was peeled from the dicing film at a peeling angle of 180° and a peeling speed of 300 mm/min was read using a tensile tester (AGS-J manufactured by Shimadzu Corporation). The results are shown in Tables 1 to 7.

### (Confirmation of Semiconductor Chip Damage During Die Bonding)

An adhesive film with a dicing film was formed by pasting a dicing film onto each of the obtained adhesive films. DU-300 manufactured by Nitto Denko Corporation was used as the dicing film. Next, a semiconductor wafer (thickness 30 μm) was pasted onto each of the adhesive films with a dicing film, and it was diced into a 10 mm square while being held by the dicing film. Subsequently, the semiconductor chip was peeled together with the adhesive film by stretching the base, and it was adhered to a lead frame under a condition such that the temperature was 120° C., the pressure was 0.1 MPa, and the time was 1 second. 20 chips were peeled for each of the adhesive films, and the number of chips was counted in which damage occurred by pressure during die bonding. As a result of counting, a case where the number damaged was 0 was marked as ◯, and a case where the number damaged was 1 or more was marked as x. The results are shown in Tables 1 to 7.

### (Solder Reflow Property)

Each of the obtained adhesive films was pasted onto a 5 mm square semiconductor chip under a condition of 40° C., and a release liner was peeled therefrom. Then, it was mounted on a lead frame under a condition such that the temperature was 120° C., the pressure was 0.1 MPa, and the time was 1 second, and it was sealed using a sealing resin (GE-100 manufactured by Nitto Denko Corporation). The resin sealing condition was such that the heating temperature was 175° C. and the heating time was 3 minutes. Thereafter, a post curing step was performed at 175° C. for 5 hours. Nine of such samples were produced for each of the adhesive films. Next, it was left for 168 hours in an atmosphere of 60° C. and 80% RH. Thereafter, it was passed through an IR reflow furnace in which the temperature was set so that 260° C. or more of the temperature could be kept for 10 seconds, and whether or not the occurrence of peeling at the interface of the semiconductor chip and the lead frame was observed with an ultrasonic microscope. As a result of the observation, an evaluation was made by marking a case where the number of chips to which peeling occurred was 0 as ◯ and a case where the number thereof was 1 or more as x. Moreover, this solder reflow property test was performed by using a semiconductor chip in which damage was not confirmed on the lead frame after mounting. The results are shown in Tables 1 to 7.

### (Result)

As is seen from the results in Tables 1 to 7, adhesive films having a tensile storage modulus at 260° C. after thermosetting of 2×10⁵ to 5×10⁷ Pa, not containing a filler, and having a thickness of 1 to 10 μm as in the examples had no damage due to pressure during bonding to the semiconductor chip and had no warping of the semiconductor chip during thermosetting. Further, the solder reflow property was excellent.

TABLE 1

| | Example 1-1 | Example 2-1 | Example 3-1 | Example 4-1 | Example 5-1 |
|---|---|---|---|---|---|
| FILLER (PARTS BY WEIGHT) | 0 | 0 | 0 | 0 | 0 |
| TENSILE STORAGE MODULUS | 4.6 × 10⁷ | 3.1 × 10⁷ | 9.3 × 10⁶ | 7.1 × 10⁵ | 2.5 × 10⁵ |
| (Pa) AT 260° C. AFTER | | | | | |
| THERMOSETTING | | | | | |
| TENSILE STORAGE MODULUS | 1.3 × 10⁴ | 9.0 × 10⁴ | 7.2 × 10⁵ | 2.1 × 10⁶ | 5.7 × 10⁵ |
| (Pa) AT 120° C. BEFORE | | | | | |
| THERMOSETTING | | | | | |
| SHEAR ADHERING STRENGTH | 0.041 | 0.074 | 0.119 | 0.222 | 0.109 |
| (MPa) | | | | | |
| SURFACE ROUGHNESS (nm) | 23 | 44 | 15 | 39 | 30 |
| GLASS TRANSITION | 44 | 38 | 31 | 29 | 18 |
| TEMPERATURE (° C.) BEFORE | | | | | |
| THERMOSETTING | | | | | |
| Tg OF ACRYLIC RESIN 1 | −13 | 12 | 7 | 7 | 12 |
| Tg OF ACRYLIC RESIN 2 | — | — | — | — | −13 |
| AMOUNT OF WARPING (μm) | 15 | 12 | 6 | 3 | 2 |
| EVALUATION OF WARPING | ◯ | ◯ | ◯ | ◯ | ◯ |
| (100 μm OR LESS) | | | | | |
| NUMBER OF DAMAGED | 0/20 | 0/20 | 0/20 | 0/20 | 0/20 |
| SEMICONDUCTOR CHIPS DURING | | | | | |
| DIE BONDING (NUMBER OF | | | | | |
| DAMAGED CHIPS/NUMBER OF | | | | | |
| ATTEMPTS) | | | | | |
| EVALUATION OF CHIP DAMAGE | ◯ | ◯ | ◯ | ◯ | ◯ |
| DURING DIE BONDING | | | | | |
| PEELING STRENGTH (N/20 mm) | 0.01 | 0.02 | 0.08 | 0.15 | 0.1 |
| SOLDER REFLOW PROPERTY | ◯ | ◯ | ◯ | ◯ | ◯ |

TABLE 2

| | | Com- | Com- | Com- | Com- | Com- | Com- | Com- | Com- |
|---|---|---|---|---|---|---|---|---|---|
| | | parative | parative | parative | parative | parative | parative | parative | parative |
| | Comparative | Example | Example | Example | Example | Example | Example | Example | Example |
| | Example 1-1 | 2-1 | 3-1 | 4-1 | 5-1 | 6-1 | 7-1 | 8-1 | 9-1 |
| FILLER (PARTS BY WEIGHT) | 0 | 0 | 10 | 50 | 25 | 25 | 10 | 70 | 20 |
| TENSILE STORAGE MODULUS | 1.0 × 10⁵ | 6.1 × 10⁷ | 4.9 × 10⁷ | 3.0 × 10⁷ | 7.1 × 10⁷ | 7.0 × 10⁷ | 1.0 × 10⁶ | 1.5 × 10⁵ | 1.2 × 10⁵ |
| (Pa) AT 260° C. AFTER | | | | | | | | | |
| THERMOSETTING | | | | | | | | | |
| TENSILE STORAGE MODULUS | 1.2 × 10⁵ | 1.5 × 10⁴ | 1.5 × 10⁵ | 3.7 × 10⁴ | 1.9 × 10⁴ | 2.5 × 10⁴ | 7.6 × 10⁵ | 3.7 × 10⁶ | 1.4 × 10⁵ |
| (Pa) AT 120° C. BEFORE | | | | | | | | | |
| THERMOSETTING | | | | | | | | | |
| SHEAR ADHERING STRENGTH | 0.098 | 0.027 | 0.038 | 0.049 | 0.03 | 0.033 | 0.076 | 0.027 | 0.035 |
| (MPa) | | | | | | | | | |
| SURFACE ROUGHNESS (nm) | 34 | 26 | 90 | 459 | 233 | 227 | 101 | 678 | 173 |
| GLASS TRANSITION | −20 | 65 | 46 | 36 | 71 | 68 | 31 | 32 | −15 |
| TEMPERATURE (° C.) BEFORE | | | | | | | | | |
| THERMOSETTING | | | | | | | | | |
| Tg OF ACRYLIC RESIN 1 | −22 | 18 | −13 | −22 | 7 | 7 | 12 | 7 | −22 |
| Tg OF ACRYLIC RESIN 2 | — | — | — | — | — | — | — | — | — |
| AMOUNT OF WARPING (μm) | 0 | 110 | 13 | 8 | 102 | 80 | 0 | 2 | 0 |
| EVALUATION OF WARPING | ◯ | X | ◯ | ◯ | X | ◯ | ◯ | ◯ | ◯ |
| (100 μm OR LESS) | | | | | | | | | |
| NUMBER OF DAMAGED | 0/20 | 0/20 | 3/20 | 20/20 | 14/20 | 14/20 | 2/20 | 20/20 | 6/20 |
| SEMICONDUCTOR CHIPS DURING | | | | | | | | | |
| DIE BONDING (NUMBER OF | | | | | | | | | |
| DAMAGED CHIPS/NUMBER OF | | | | | | | | | |
| ATTEMPTS) | | | | | | | | | |
| EVALUATION OF CHIP DAMAGE | ◯ | ◯ | X | X | X | X | X | X | X |
| DURING DIE BONDING | | | | | | | | | |
| PEELING STRENGTH (N/20 mm) | 0.23 | 0.004 | 0.01 | 0.015 | 0.003 | 0.003 | 0.08 | 0.14 | 0.2 |
| SOLDER REFLOW PROPERTY | X | ◯ | ◯ | ◯ | ◯ | ◯ | ◯ | X | X |

TABLE 3

| | Example 1-2 | Example 2-2 | Example 3-2 | Example 4-2 | Example 5-2 |
|---|---|---|---|---|---|
| FILLER (PARTS BY WEIGHT) | 0 | 0 | 0 | 0 | 0 |
| TENSILE STORAGE MODULUS | 4.6 × 10⁷ | 3.1 × 10⁷ | 9.3 × 10⁶ | 7.1 × 10⁵ | 2.5 × 10⁵ |
| (Pa) AT 260° C. AFTER | | | | | |
| THERMOSETTING | | | | | |
| TENSILE STORAGE MODULUS | 1.3 × 10⁴ | 9.0 × 10⁴ | 7.2 × 10⁵ | 2.1 × 10⁶ | 5.7 × 10⁵ |
| (Pa) AT 120° C. BEFORE | | | | | |
| THERMOSETTING | | | | | |
| SHEAR ADHERING STRENGTH | 0.053 | 0.088 | 0.156 | 0.755 | 0.131 |
| (MPa) | | | | | |
| SURFACE ROUGHNESS (nm) | 34 | 12 | 19 | 32 | 15 |
| GLASS TRANSITION | 44 | 38 | 31 | 29 | 18 |
| TEMPERATURE (° C.) BEFORE | | | | | |
| THERMOSETTING | | | | | |
| Tg OF ACRYLIC RESIN 1 | −13 | 12 | 7 | 7 | 12 |
| Tg OF ACRYLIC RESIN 2 | — | — | — | — | −13 |
| AMOUNT OF WARPING (μm) | 25 | 19 | 9 | 5 | 3 |
| EVALUATION OF WARPING | ◯ | ◯ | ◯ | ◯ | ◯ |
| (100 μm OR LESS) | | | | | |
| NUMBER OF DAMAGED | 0/20 | 0/20 | 0/20 | 0/20 | 0/20 |
| SEMICONDUCTOR CHIPS DURING | | | | | |
| DIE BONDING (NUMBER OF | | | | | |
| DAMAGED CHIPS/NUMBER OF | | | | | |
| ATTEMPTS) | | | | | |
| EVALUATION OF CHIP DAMAGE | ◯ | ◯ | ◯ | ◯ | ◯ |
| DURING DIE BONDING | | | | | |
| PEELING STRENGTH (N/20 mm) | 0.01 | 0.02 | 0.08 | 0.15 | 0.1 |
| SOLDER REFLOW PROPERTY | ◯ | ◯ | ◯ | ◯ | ◯ |

TABLE 4

| | | Com- | Com- | Com- | Com- | Com- | Com- | Com- | Com- |
|---|---|---|---|---|---|---|---|---|---|
| | | parative | parative | parative | parative | parative | parative | parative | parative |
| | Comparative | Example | Example | Example | Example | Example | Example | Example | Example |
| | Example 1-2 | 2-2 | 3-2 | 4-2 | 5-2 | 6-2 | 7-2 | 8-2 | 9-2 |
| FILLER (PARTS BY WEIGHT) | 0 | 0 | 10 | 50 | 25 | 25 | 10 | 70 | 20 |
| TENSILE STORAGE MODULUS | 1.0 × 10⁵ | 6.1 × 10⁷ | 4.9 × 10⁷ | 3.0 × 10⁷ | 7.1 × 10⁷ | 7.0 × 10⁷ | 1.0 × 10⁶ | 1.5 × 10⁵ | 1.2 × 10⁵ |
| (Pa) AT 260° C. AFTER | | | | | | | | | |
| THERMOSETTING | | | | | | | | | |
| TENSILE STORAGE MODULUS | 1.2 × 10⁵ | 1.5 × 10⁴ | 1.5 × 10⁵ | 3.7 × 10⁴ | 1.9 × 10⁴ | 2.5 × 10⁴ | 7.6 × 10⁵ | 3.7 × 10⁶ | 1.4 × 10⁵ |
| (Pa) AT 120° C. BEFORE | | | | | | | | | |
| THERMOSETTING | | | | | | | | | |
| SHEAR ADHERING STRENGTH | 0.122 | 0.029 | 0.043 | 0.061 | 0.031 | 0.037 | 0.081 | 0.03 | 0.045 |
| (MPa) | | | | | | | | | |
| SURFACE ROUGHNESS (nm) | 33 | 18 | 76 | 333 | 166 | 154 | 84 | 598 | 145 |
| GLASS TRANSITION | −20 | 65 | 46 | 36 | 71 | 68 | 31 | 32 | −15 |
| TEMPERATURE (° C.) BEFORE | | | | | | | | | |
| THERMOSETTING | | | | | | | | | |
| Tg OF ACRYLIC RESIN 1 | −22 | 18 | −13 | −22 | 7 | 7 | 12 | 7 | −22 |
| Tg OF ACRYLIC RESIN 2 | — | — | — | — | — | — | — | — | — |
| AMOUNT OF WARPING (μm) | 0 | 195 | 20 | 14 | 172 | 133 | 0 | 2 | 1 |
| EVALUATION OF WARPING | ◯ | X | ◯ | ◯ | X | X | ◯ | ◯ | ◯ |
| (100 μm OR LESS) | | | | | | | | | |
| NUMBER OF DAMAGED | 0/20 | 0/20 | 2/20 | 18/20 | 9/20 | 10/20 | 2/20 | 19/20 | 5/20 |
| SEMICONDUCTOR CHIPS DURING | | | | | | | | | |
| DIE BONDING (NUMBER OF | | | | | | | | | |
| DAMAGED CHIPS/NUMBER OF | | | | | | | | | |
| ATTEMPTS) | | | | | | | | | |
| EVALUATION OF CHIP DAMAGE | ◯ | ◯ | X | X | X | X | X | X | X |
| DURING DIE BONDING | | | | | | | | | |
| PEELING STRENGTH (N/20 mm) | 0.23 | 0.004 | 0.01 | 0.015 | 0.003 | 0.003 | 0.08 | 0.14 | 0.2 |
| SOLDER REFLOW PROPERTY | X | ◯ | ◯ | ◯ | ◯ | ◯ | ◯ | X | X |

TABLE 5

| | Example 1-3 | Example 2-3 | Example 3-3 | Example 4-3 | Example 5-3 |
|---|---|---|---|---|---|
| FILLER (PARTS BY WEIGHT) | 0 | 0 | 0 | 0 | 0 |
| TENSILE STORAGE MODULUS | 4.6 × 10⁷ | 3.1 × 10⁷ | 9.3 × 10⁶ | 7.1 × 10⁵ | 2.5 × 10⁵ |
| (Pa) AT 260° C. AFTER | | | | | |
| THERMOSETTING | | | | | |
| TENSILE STORAGE MODULUS | 1.3 × 10⁴ | 9.0 × 10⁴ | 7.2 × 10⁵ | 2.1 × 10⁶ | 5.7 × 10⁵ |
| (Pa) AT 120° C. BEFORE | | | | | |
| THERMOSETTING | | | | | |
| SHEAR ADHERING STRENGTH | 0.054 | 0.088 | 0.16 | 0.92 | 0.133 |
| (MPa) | | | | | |
| SURFACE ROUGHNESS (nm) | 23 | 27 | 31 | 19 | 9 |
| GLASS TRANSITION | 44 | 38 | 31 | 29 | 18 |
| TEMPERATURE (° C.) BEFORE | | | | | |
| THERMOSETTING | | | | | |
| Tg OF ACRYLIC RESIN 1 | −13 | 12 | 7 | 7 | 12 |
| Tg OF ACRYLIC RESIN 2 | — | — | — | — | −13 |
| AMOUNT OF WARPING (μm) | 50 | 37 | 20 | 10 | 5 |
| EVALUATION OF WARPING | ◯ | ◯ | ◯ | ◯ | ◯ |
| (100 μm OR LESS) | | | | | |
| NUMBER OF DAMAGED | 0/20 | 0/20 | 0/20 | 0/20 | 0/20 |
| SEMICONDUCTOR CHIPS DURING | | | | | |
| DIE BONDING (NUMBER OF | | | | | |
| DAMAGED CHIPS/NUMBER OF | | | | | |
| ATTEMPTS) | | | | | |
| EVALUATION OF CHIP DAMAGE | ◯ | ◯ | ◯ | ◯ | ◯ |
| DURING DIE BONDING | | | | | |
| PEELING STRENGTH (N/20 mm) | 0.01 | 0.02 | 0.08 | 0.15 | 0.1 |
| SOLDER REFLOW PROPERTY | ◯ | ◯ | ◯ | ◯ | ◯ |

TABLE 6

| | | Com- | Com- | Com- | Com- | Com- | Com- | Com- | Com- |
|---|---|---|---|---|---|---|---|---|---|
| | | parative | parative | parative | parative | parative | parative | parative | parative |
| | Comparative | Example | Example | Example | Example | Example | Example | Example | Example |
| | Example 1-3 | 2-3 | 3-3 | 4-3 | 5-3 | 6-3 | 7-3 | 8-3 | 9-3 |
| FILLER (PARTS BY WEIGHT) | 0 | 0 | 10 | 50 | 25 | 25 | 10 | 70 | 20 |
| TENSILE STORAGE MODULUS | 1.0 × 10⁵ | 6.1 × 10⁷ | 4.9 × 10⁷ | 3.0 × 10⁷ | 7.1 × 10⁷ | 7.0 × 10⁷ | 1.0 × 10⁶ | 1.5 × 10⁵ | 1.2 × 10⁵ |
| (Pa) AT 260° C. AFTER | | | | | | | | | |
| THERMOSETTING | | | | | | | | | |
| TENSILE STORAGE MODULUS | 1.2 × 10⁵ | 1.5 × 10⁴ | 1.5 × 10⁵ | 3.7 × 10⁴ | 1.9 × 10⁴ | 2.5 × 10⁴ | 7.6 × 10⁵ | 3.7 × 10⁶ | 1.4 × 10⁵ |
| (Pa) AT 120° C. BEFORE | | | | | | | | | |
| THERMOSETTING | | | | | | | | | |
| SHEAR ADHERING STRENGTH | 0.122 | 0.029 | 0.044 | 0.084 | 0.036 | 0.041 | 0.113 | 0.03 | 0.048 |
| (MPa) | | | | | | | | | |
| SURFACE ROUGHNESS (nm) | 13 | 17 | 53 | 276 | 76 | 61 | 57 | 388 | 99 |
| GLASS TRANSITION | −20 | 65 | 46 | 36 | 71 | 68 | 31 | 32 | −15 |
| TEMPERATURE (° C.) BEFORE | | | | | | | | | |
| THERMOSETTING | | | | | | | | | |
| Tg OF ACRYLIC RESIN 1 | −22 | 18 | −13 | −22 | 7 | 7 | 12 | 7 | −22 |
| Tg OF ACRYLIC RESIN 2 | — | — | — | — | — | — | — | — | — |
| AMOUNT OF WARPING (μm) | 1 | 401 | 46 | 27 | 350 | 260 | 1 | 4 | 2 |
| EVALUATION OF WARPING | ◯ | X | ◯ | ◯ | X | X | ◯ | ◯ | ◯ |
| (100 μm OR LESS) | | | | | | | | | |
| NUMBER OF DAMAGED | 0/20 | 0/20 | 1/20 | 8/20 | 9/20 | 4/20 | 1/20 | 12/20 | 3/20 |
| SEMICONDUCTOR CHIPS DURING | | | | | | | | | |
| DIE BONDING (NUMBER OF | | | | | | | | | |
| DAMAGED CHIPS/NUMBER OF | | | | | | | | | |
| ATTEMPTS) | | | | | | | | | |
| EVALUATION OF CHIP DAMAGE | ◯ | ◯ | X | X | X | X | X | X | X |
| DURING DIE BONDING | | | | | | | | | |
| PEELING STRENGTH (N/20 mm) | 0.23 | 0.004 | 0.01 | 0.015 | 0.003 | 0.003 | 0.08 | 0.14 | 0.2 |
| SOLDER REFLOW PROPERTY | X | ◯ | ◯ | ◯ | ◯ | ◯ | ◯ | X | X |

TABLE 7

| | Comparative | Comparative | Comparative |
|---|---|---|---|
| | Example 1-4 | Example 2-4 | Example 3-4 |
| FILLER (PARTS BY WEIGHT) | 0 | 0 | 10 |
| TENSILE STORAGE MODULUS | 4.6 × 10⁷ | 3.1 × 10⁷ | 4.9 × 10⁷ |
| (Pa) AT 260° C. AFTER | | | |
| THERMOSETTING | | | |
| TENSILE STORAGE MODULUS | 1.3 × 10⁴ | 9.0 × 10⁴ | 1.5 × 10⁵ |
| (Pa) AT 120° C. BEFORE | | | |
| THERMOSETTING | | | |
| SHEAR ADHERING STRENGTH | 0.055 | 0.089 | 0.045 |
| (MPa) | | | |
| SURFACE ROUGHNESS (nm) | 33 | 21 | 36 |
| GLASS TRANSITION | 44 | 38 | 46 |
| TEMPERATURE (° C.) BEFORE | | | |
| THERMOSETTING | | | |
| Tg OF ACRYLIC RESIN 1 | −13 | 12 | −13 |
| Tg OF ACRYLIC RESIN 2 | — | — | — |
| AMOUNT OF WARPING (μm) | 120 | 102 | 115 |
| EVALUATION OF WARPING | X | X | X |
| (100 μm OR LESS) | | | |
| NUMBER OF DAMAGED | 0/20 | 0/20 | 0/20 |
| SEMICONDUCTOR CHIPS DURING DIE | | | |
| BONDING (NUMBER OF | | | |
| DAMAGED CHIPS/NUMBER OF | | | |
| ATTEMPTS) | | | |
| EVALUATION OF CHIP DAMAGE | ◯ | ◯ | ◯ |
| DURING DIE BONDING | | | |
| PEELING STRENGTH (N/20 mm) | 0.01 | 0.02 | 0.01 |
| SOLDER REFLOW PROPERTY | ◯ | ◯ | ◯ |

1. A thermosetting adhesive film used at the time of manufacturing a semiconductor device, the film having
a tensile storage modulus at 260° C. after thermosetting of 2×10⁵ to 5×10⁷ Pa,
a content of a filler of at most 0.1% by weight based on the entire thermosetting adhesive film, and
a thickness of 1 to 10 μm.

2. The thermosetting adhesive film according to claim 1, wherein the film has a glass transition temperature before thermosetting of 15 to 50° C.

3. The thermosetting adhesive film according to claim 1, wherein the film contains an acrylic resin, and the acrylic resin has a glass transition temperature of −15 to 15° C.

4. The thermosetting adhesive film according to claim 1, wherein the film contains an epoxy resin, a phenol resin, and an acrylic resin, and has B/(A+B) of 0.15 to 0.95, where A represents a total weight of the epoxy resin, the phenol resin, and the acrylic resin and B represents a weight of the acrylic resin.

5. The thermosetting adhesive film according to claim 1, wherein the film has an amount of warping after thermosetting of at most 100 μm.

6. The thermosetting adhesive film according to claim 1, wherein the film has a shear adhering strength to a silicon substrate before thermosetting of 0.04 to 2 MPa under a condition of 175° C.

7. The thermosetting adhesive film according to claim 1, wherein the film has a surface roughness before thermosetting of at most 50 nm.

8. The thermosetting adhesive film according to claim 1, wherein the film has a tensile storage modulus at 120° C. before thermosetting of 1×10⁴ to 2.5×10⁶ Pa.

9. An adhesive film with a dicing film, the film comprising the thermosetting adhesive film according to claim 1 laminated on the dicing film.

10. The adhesive film with a dicing film according to claim 9, wherein the thermosetting adhesive film has a peeling strength of 0.005 to 0.2 N/20 mm from the dicing film.

11. A method of manufacturing a semiconductor device using the thermosetting adhesive film according to claim 1, wherein
a die bonding temperature is 80 to 150° C., a die bonding pressure is 0.05 to 5 MPa, and a die bonding time is 0.1 to 5 seconds in a die bonding step in which a semiconductor chip is die-bonded to an adherend through the thermosetting adhesive film.

12. A method of manufacturing a semiconductor device using the adhesive film with a dicing film according to claim 9, wherein
a die bonding temperature is 80 to 150° C., a die bonding pressure is 0.05 to 5 MPa, and a die bonding time is 0.1 to 5 seconds in a die bonding step in which a semiconductor chip is die-bonded to an adherend through the thermosetting adhesive film.

13. The thermosetting adhesive film according to claim 1, wherein the thermosetting adhesive film is present as a single body of an adhesive film.

14. The thermosetting adhesive film according to claim 1, wherein the thermosetting adhesive film is configured on a first side of a pressure-sensitive adhesive layer, and a base material is configured on a second side of the pressure-sensitive adhesive layer.

15. The thermosetting adhesive film according to claim 1, wherein the filler is selected from the group consisting of aluminum hydroxide, magnesium hydroxide, calcium hydroxide, antimony trioxide, calcium carbonate, magnesium carbonate, calcium silicate, magnesium silicate, calcium oxide, magnesium oxide, aluminum oxide, aluminum nitride, aluminum borate, boron nitride, crystalline silica, and amorphous silica.
